(19) United States
(12) Patent Application Publication
(10) Pub. No.: US 2019/0259950 A1
(43) Pub. Date: Aug. 22, 2019

(54) ALLOY METAL FOIL FOR USE AS DEPOSITION MASK, DEPOSITION MASK, METHODS OF PREPARING THE SAME, AND METHOD OF MANUFACTURING ORGANIC LIGHT-EMITTING DEVICE USING THE SAME

(71) Applicant: POSCO, Pohang-si (KR)

(72) Inventors: Gwan-Ho JUNG, Pohang-si (KR); Hong-Seok YANG, Pohang-si (KR); Jae-Kon LEE, Pohang-si (KR); Hyun-Tae KIM, Pohang-si (KR); Ki-Soo KIM, Pohang-si (KR)

(73) Assignee: POSCO, Pohang-si (KR)

(21) Appl. No.: 16/330,959

(22) PCT Filed: Sep. 21, 2017
(86) PCT No.: PCT/KR2017/010382

§ 371 Date: Mar. 6, 2019

(30) Foreign Application Priority Data
Oct. 6, 2016 (KR) 10-2016-0129265

(51) Int. Cl. H01L 51/00; C23C 14/04; C22C 38/08; C25D 1/10; H01L 51/56

(52) U.S. Cl. CPC H01L 51/0011; C23C 14/042; C22C 38/08; C23F 1/02; H01L 51/001; H01L 51/56; C25D 1/10

(57) ABSTRACT

Provided are a deposition mask having a plurality of fine through-holes formed on a metal foil; a metal foil to be used therein; manufacturing methods therefor; and an organic EL device manufacturing method using the deposition mask, and an Fe—Ni alloy metal foil to be used as a deposition mask, including 34-46 wt % of Ni and the balance of Fe and inevitable impurities. The metal foil includes a pattern formation area and an uncoated area on at least one surface thereof, the pattern formation area is thinner than the uncoated area and has low surface roughness, and the uncoated area is positioned at the edge of the metal foil so as to surround the pattern formation area.

### TECHNICAL FIELD

The present disclosure relates to a deposition mask having a plurality of fine through-holes formed on a metal foil, a metal foil for use for the same, and methods of preparing the deposition mask and the metal foil. In addition, the present disclosure relates to a method of manufacturing an organic EL device.

### BACKGROUND ART

Recently, as there has been increasing demand for virtual reality (VR) devices along with popularization of smart devices, more attention has been placed on organic electroluminescent (EL) devices having fast response speed, a wide field of view, and excellent contrast as well as low energy consumption rate. In particular, since higher resolutions of VR provide more realistic experience, there has been increasing demand for upcoming VR devices to have higher resolution.

To manufacture an organic EL display of high resolution, refinement of display device pixels is necessary. To form pixels of such organic EL displays, there has been known a method that forms pixels in a desired pattern by using a deposition mask having perforations in an arrangement of a desired pattern. In particular, by attaching a deposition mask having arrangements of perforations to an organic EL display substrate, and by using a vacuum deposition technique, pixels of organic material are deposited.

Generally, a deposition mask can be produced by coating a photoresist membrane on a metal foil, forming a photoresist pattern through photolithography, and then forming perforations (through-holes) on the metal foil through wet-etching or dry-etching.

However, as the pixel refinement of display devices is becoming increasingly more necessary, the roughness of the base material of a deposition mask, that is, a metal foil, has emerged as an increasingly more important characteristic. Since patterns, when formed on metal foils with high roughness, are likely to be inaccurate in shape and decrease in uniformity, such metal foils with high roughness value may not be suitable for use in producing a deposition mask of high resolution.

Furthermore, there are technical difficulties in manufacturing patterns with high resolution by using relatively thick metal foils of about 50-100 μm. For example, when through-hole patterns are formed on a thick metal foil, there may be undesirable interference between the patterns, thus hindering accurate pattern formation.

As a solution to address the above-mentioned problems, it may be possible to use a method whereby a metal foil is produced to have a relatively small thickness; however, when the thickness becomes too small, 20 μm or less, there may be an undesirable degradation of strength, and handling difficulties, which may potentially give rise to disfiguration of a substrate when producing deposition masks.

### DISCLOSURE

### Technical Problem

Embodiments of the present disclosure are derived to address the above-described issues, and in particular, may provide: a metal foil which enables precise formation of micropatterns when etching a metal foil to produce a deposition mask; and a deposition mask including micropatterns.

In addition, the present disclosure may provide: a metal foil which, when producing a deposition mask with a plurality of through-holes on the basis of such metal foils, can maintain strength of the deposition mask; and a deposition mask.

### Technical Solution

One aspect of the present disclosure provides a Fe—Ni alloy metal foil for use as a deposition mask, and the metal foil according to an embodiment is a Fe—Ni alloy metal foil for use as a deposition mask, which includes 34-wt % of nickel (Ni) and a balance of iron (Fe) and inevitable impurities, wherein the metal foil includes a pattern formation area and an uncoated area on at least one surface thereof, wherein the pattern formation area is thinner than the uncoated area and has a lower surface roughness value than that of the uncoated area, and the uncoated area is positioned at an edge of the pattern formation area so as to surround the pattern formation area.

The pattern formation area may have a thickness that is 25-88% of the thickness of the uncoated area, whereas the pattern formation area may have a thickness in the range of 5-15 μm.

The Fe—Ni alloy metal foil is produced by electroforming, and the pattern formation area has a lower surface roughness value than the surface roughness value of the uncoated area. For example, a surface roughness value of the pattern formation area may be greater than or equal to 30% and less than or equal to 80% of a surface roughness value of the uncoated area.

Another aspect of the present disclosure provides a method of preparing a Fe—Ni alloy metal foil for use as a deposition mask, the method being characterized by performing chemical polishing on an inner area, excluding an edge, of one side of a Fe—Ni alloy metal foil containing 34-46 wt % of nickel (Ni) and a balance of iron (Fe) and inevitable impurities, to thin the inner area.

In addition, an operation of performing chemical polishing on the entire area of the other side of the Fe—Ni alloy metal foil to thin the same may be further included.

Another aspect of the present disclosure provides a deposition mask formed of a Fe—Ni alloy metal foil having through-holes having a predetermined pattern formed thereon, wherein the deposition mask includes, on one side thereof, a pattern formation area including the through-holes of a predetermined pattern, and an uncoated area thicker than the pattern formation area and not containing through-holes.

The pattern formation area may have a thickness that corresponds to 25-88% of the thickness of the uncoated area. For example, the pattern formation area may have a thickness in the range of 5-15 μm.

The through-holes have inner walls which are inclined so as to allow gaps between the through-holes to be wider on the other side of the metal foil than on the gaps on the one side including the pattern formation area and the uncoated area.

The Fe—Ni alloy metal foil may be formed by electroforming, and the surface roughness value of the pattern formation area may be lower than a surface roughness value of the uncoated area.

A surface roughness value of the pattern formation area may be greater than or equal to 30% and less than or equal to 80% of a surface roughness value of the uncoated area.

Inner wall surfaces of the through-hole may include a plurality of stripe patterns in a direction parallel to a surface of the deposition mask.

The other side of the deposition mask, opposite to the one side including the pattern formation area and the uncoated area, may have a surface roughness value lower than a surface roughness value of the uncoated area.

Another aspect of the present disclosure provides a method of producing a deposition mask, wherein the deposition mask has a plurality of through-holes formed by forming a photoresist pattern in an inner area of the above-prepared Fe—Ni alloy metal foil for use as a deposition mask, and then etching the same.

The through-holes may be formed by forming, on the other side of the alloy metal foil, another photoresist pattern that corresponds to the photoresist pattern, followed by etching.

In addition, another aspect of the present disclosure provides a method of manufacturing an organic EL element, the method comprising an operation of laminating the above-provided deposition mask on an organic EL display substrate and vacuum-depositing a deposition target organic material to thereby transfer a mask pattern.

### Advantageous Effects

According to exemplary embodiments of the present disclosure, by controlling the roughness of the base material of a deposition mask, a metal foil, it may be possible to provide a metal foil capable of ultra-precise refinement of patterns and having high uniformity between patterns, and a deposition mask.

In addition, by using a metal foil which is the base material of a deposition mask and a method of preparing a deposition mask according to embodiments of the present disclosure, it may be possible to provide a deposition mask exhibiting the above-described characteristics while maintaining strength.

### DESCRIPTION OF DRAWINGS

FIG. 1 is a diagram illustrating, as an example, a process flow for producing a deposition mask.

FIG. 2 is a graph schematically illustrating changes in surface roughness of metal foils in accordance with a chemical polishing time.

FIG. 3 is plan view images of 3D profile of a surface of a metal foil in accordance with a chemical polishing time.

FIG. 4 is perspective view images of 3D profile of a surface of a metal foil in accordance with a chemical polishing time.

FIG. 5 is optical images of through-holes formed on a metal foil, when forming patterns by etching on a metal foils without or after chemical polishing.

### BEST MODE FOR INVENTION

Recently, as pixel refinement has become necessary, when forming through-hole patterns with a relatively thick metal foil of about 50-100 μm, this excessive thickness of the metal foil may give rise technical difficulties in obtaining patterns of high resolution, and for example, interference between patterns may arise during an etching process, thus hindering accurate pattern formation. Meanwhile, a relatively thin metal foil of about 20 μm or less, when used to form through-hole patterns, may degrade strength and cause substrate deformation and the like in producing a deposition mask, and are often accompanied by working and handling difficulties.

In this context, the present disclosure provides a method of producing a deposition mask in which patterns can be formed accurately while using a relatively thick metal foil; and a deposition mask prepared thereby.

The present disclosure uses a Fe—Ni alloy as a deposition mask, and any material that contains 34-46 wt % of nickel (Ni) and a balance of iron (Fe) and inevitable impurities may be used as the Fe—Ni alloy without particular limitations.

Metal foils obtained by an electroforming method, as well as metal foils obtained by a rolling method, may be used as the Fe—Ni metal foil.

The rolling method is a method in which metal foils are produced by casting iron (Fe) and nickel (Ni) into ingots and then rolling and annealing the same repeatedly. The Fe—Ni based alloy metal foils produced by such a rolling method have high percent elongation and flat surfaces, and thus are advantageously resistant to cracking. However, due to mechanical limitations in production, metal foils having widths exceeding 1 m may be difficult to produce, and producing ultra-thin foils (50 μm or less) may incur an excessive production cost. Furthermore, even when metal foils are to be produced by such a rolling method, despite disadvantageous manufacturing cost, the average grain size of structures may be too coarse, thus causing degradations of mechanical properties.

Alternatively, the electroforming method is a method in which metal foils are produced by supplying electrolyte through a liquid injection nozzle, thereby passing an electric current, into a gap surrounded with a pair of curved anodes facing a cylindrical cathode drum, thereafter depositing a metal on the surface of the cathode drum, and then removing the deposited metal before coiling the same. The metal foils produced by such an electroforming method, due to a relatively small average grain size, exhibit desirable mechanical properties, and can be manufactured at a relatively low manufacturing cost, thus providing advantages in terms of manufacturing cost.

Typically, metal foils formed through the electroforming method have high roughness, and having high surface roughness causes many issues when forming micropatterns of through-holes. For example, if photoresist patterns are formed on a flat surface with high roughness, the patterns may be distorted and unable to form a normal shape, and when etching such patterns, contours forming the patterns may be formed non-linearly. Consequently, the through-holes would be distorted, causing the shape of the organic material deposited using these holes to deviate from a desired shape initially sought to be formed, and furthermore, such shape irregularities may spread at large.

In view of the foregoing, in the present disclosure, in regard to metal foils formed by the electroforming method, as well as metal foils formed by the rolling method, it is necessary to form patterns accurately even when a thick metal foil is used for the reason of handling convenience during operation; and particularly when a metal foil formed by the electroforming method is used, it is necessary to keep its surface roughness low and form micropatterns of through-holes thereon.

In this context, the present disclosure comprises an operation of chemically polishing one side of a metal foil. Here, it is preferable that chemical polishing of the metal foil be performed, not on an entire surface thereof, but partially only on an area including through-holes, that is, a pattern formation area. If the entire surface is to be polished, it may be sufficient to use a metal foil having a predetermined thickness; however, in this case, the metal foil is too thin to facilitate the precise formation of through-holes.

More particularly, the chemical polishing is performed on an area of one side of the metal foil that excludes an edge of the metal foil, that is, a pattern formation area in which a pattern by through-holes will be formed. By such chemical polishing, the pattern formation area may be formed to an appropriate thickness that may enable precise formation of through-holes.

Also, in a similar manner as to the metal foil obtained by the electroforming method, when the metal foil has high surface roughness, such chemical polishing may be performed to bring down the surface roughness and thereby may prevent the contour of a through-hole pattern from being non-linearly formed when forming the through-hole pattern by etching.

Further, by permitting an edge of the metal foil to remain as an uncoated area, without performing chemical polishing thereon, mechanical strength can be imparted to the overall metal foil, thus being able to secure handling convenience during operation. More particularly, the uncoated area may serve to protect the mask from distortion while being handled, and when the disposition mask is fixed to an invar frame during the manufacturing of an organic EL display, the outer uncoated area serves to provide hardness to the mask that prevents sagging of the same, and thus may enable more precise transfer of the patterns.

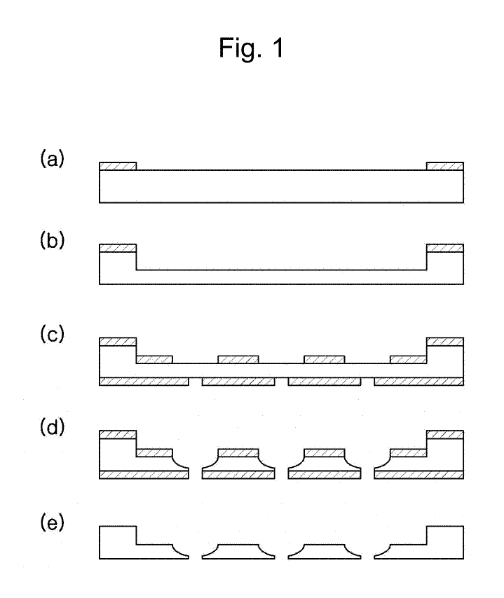

For the partial chemical polishing, as illustrated in the step (a) of FIG. 1 showing a process flow of producing a deposition mask of the present disclosure, a protective layer capable of protecting a metal surface from a chemical polishing solution may be formed prior to performing chemical polishing, to allow the edge of the metal foil to remain as an uncoated area.

For the protective layer, a photoresist may be used, and the photoresist, once coated on the entire area of the metal foil, may be separated into the pattern formation area and the uncoated area by using a photolithography process. For the type of the photoresist, both liquid type and film type may be used in the present disclosure.

According to necessity, along with partial polishing on one side of the metal foil, chemical polishing may be performed on the other side of the metal foil as well. Here, chemical polishing on the other side may be performed partially on a part of the other side that corresponds to the pattern formation area on the one side, or may be performed on an entire area of the other side. By polishing the other side and thereby reducing surface roughness of the other side, adhesion upon lamination on a substrate may be enhanced, thus promoting precise transfer of patterns.

Accordingly, as illustrated as an example in (b) of FIG. 1, a Fe—Ni alloy metal foil usable as a deposition mask can be produced. The metal foil thus obtained, as can be seen in (b) of FIG. 1, shows a substantial difference in thickness between the uncoated area and the pattern formation area. That is, the pattern formation area, by being polished through chemical polishing, is thinner than the uncoated area, thus enabling more precise formation of through-hole patterns.

Here, since chemical polishing can be performed in a controlled manner to allow the pattern formation area obtained by the chemical polishing to have a level of thickness that enables precise formation of through-hole patterns, the thickness of the pattern formation area is not particularly limited, but the chemical polishing may be performed so that the thickness is, for example, in the range of 5-40 μm, more preferably in the range of 5-29 μm. The pattern formation area having a thickness in the above range may realize through-holes with high precision more easily.

By chemical polishing, the pattern formation area may be controlled to have a thickness that is 25-88% of the thickness of the metal foil provided as base material, that is, the thickness of the uncoated area thereof. When the pattern formation area has a thickness greater than the above range, a decrease in thickness of the pattern formation area by chemical polishing may be too small to fully benefit the formation of through-holes; alternatively, the pattern formation area having a thickness less than the above range, although it benefits the precise formation of through-hole pattern, causes the chemical polishing to be relatively time-consuming, while contributing little to surface planarization through lowering the surface roughness.

Also, by such chemical polishing, the surface of the pattern formation area may be planarized so as to have a surface roughness value significantly lower than that of the uncoated area. With increasing chemical polishing time, the surface roughness value decreases, thus contributing to surface planarization, but a degree to which it contributes to the surface planarization tends to gradually decrease.

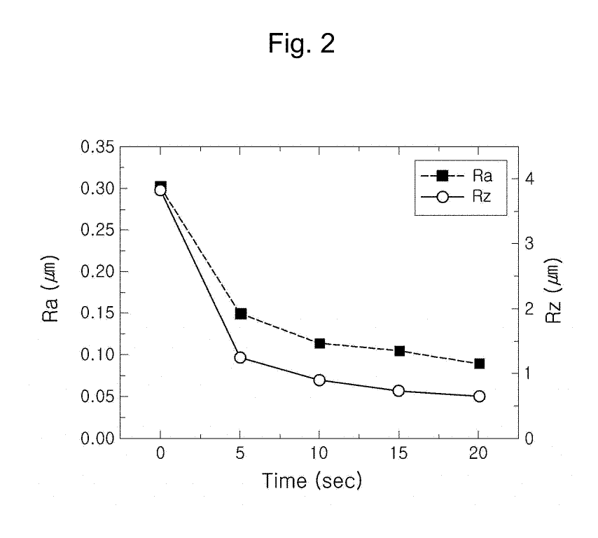

FIG. 2 is a graph schematically showing changes in surface roughness of metal foils in accordance with a chemical polishing time. As can be seen in FIG. 2, both Ra and Rz were found to have a tendency to decrease with increasing chemical polishing time. Such decrease in surface roughness is obtained more effectively with a metal foil obtained by the electroforming method, and in the present disclosure, it may be preferable that chemical polishing be performed so as to allow a surface roughness value of the pattern formation area to be in the range of 30-80% with respect to a surface roughness value of the uncoated area.

Of the Fe—Ni alloy metal foil used as a deposition mask, obtained by the above-described method, a predetermined photoresist pattern may be formed in the pattern formation area, as shown in FIG. 1 (c). In regard to the photoresist pattern, the photoresist pattern may be formed in accordance with a desired through-hole pattern in the pattern formation area by using commonly practiced methods. Here, the photoresist pattern is formed on a part of the other side of the metal foil as well, the part corresponding to a part of the pattern formation area in which the through-holes will be later formed.

Subsequently, as shown in FIG. 1 (d), a part on which the photoresist pattern is not formed may be etched with an etching solution to form through-holes. The etching may be performed on the pattern formation area to thereby form the through-holes. Also, the etching may be performed to first etch the pattern formation area to a predetermined thickness, and then etch the other side with an etching solution to thereby form through-holes.

As described above, when the through-holes are formed by first etching the side including the pattern formation area to a predetermined depth, and then etching the other side and thereby perforating the metal foil, as can be seen from FIGS. 1 (d) and (e), the through-hole thus obtained has a structure where inner wall surface of the through-hole is formed such that a width of the through-hole becomes narrower from the one side towards the other side, wherein a part at which the width of the through-hole is the smallest is positioned in a middle portion of a cross-section of the metal foil.

Once the through-holes of a desired pattern are formed, the photoresist formed on the surface of the metal foil may be removed to thereby produce a deposition mask as illustrated in FIG. 1 (e).

When the Fe—Ni alloy metal foil is a metal foil obtained by the electroforming method, it could be confirmed that a plurality of stripe patterns are formed on the inner wall surface of the through-hole. The stripe patterns formed in a planar direction, which may be formed on the inside of a metal foil formed by electroforming, are the parts that play an important role in obtaining a decent surface in a previously performed chemical polishing which polishes a surface layer in a layer by layer manner.

By laminating the mask thus obtained on an organic EL display substrate, followed by vacuum depositing a deposition target organic material in the same pattern as the patterns of the mask, an organic EL element may be produced.

For example, for the deposition of organic material by using a deposition mask according to the present disclosure, the deposition mask is used by being attached to a substrate sought to be deposited upon, and to this end, the deposition mask becomes fixed to a thick invar frame. While going through such various processes, a deposition mask having low strength may cause a defect or may be rendered unusable. Meanwhile, the deposition mask according to the present invention, while having an extremely thin pattern formation area that allows precise formation of through-hole patterns, includes an uncoated area disposed on an edge thereof that serves to increase the overall strength of the mask, thus reducing defect rates and improving handling efficiency during the manufacturing process.

Hereinbelow, the present disclosure is described in greater detail in conjunction with embodiments. However, the embodiments described herein are merely illustrative, and not restrictive on the scope of the present disclosure.

Chemical polishing was performed by using an etching solution (sulfuric acid 13.5 wt %, hydrogen peroxide 1.5 wt %, and purified water 85%) on Fe—Ni alloy metal foils (15 μm thick) produced by an electroforming method and comprising 36-46 wt % of nickel (Ni). The chemical polishing was performed at a surface etching rate of 0.2 μm/sec, and the chemical polishing time was controlled as presented in Table 1.

The metal foils thus obtained were each measured for surface roughnesses, Ra and Rz, and the results thereof were presented in Table 1. Also, the results were presented as graphs in Table 2.

TABLE 1

| | Polishing time | | |
|---|---|---|---|
| | (sec) | Ra (μm) | Rz (μm) |
| Comparative | 0 | 0.302 | 3.832 |
| Example 1 | | | |
| Inventive | 5 | 0.150 | 1.242 |
| Example 1 | | | |
| Inventive | 10 | 0.115 | 0.905 |
| Example 2 | | | |
| Inventive | 15 | 0.105 | 0.736 |
| Example 3 | | | |
| Inventive | 20 | 0.090 | 0.649 |
| Example 4 | | | |

From Table 1 and FIG. 2, it could be confirmed that surface roughnesses were significantly lowered in accordance with the polishing time.

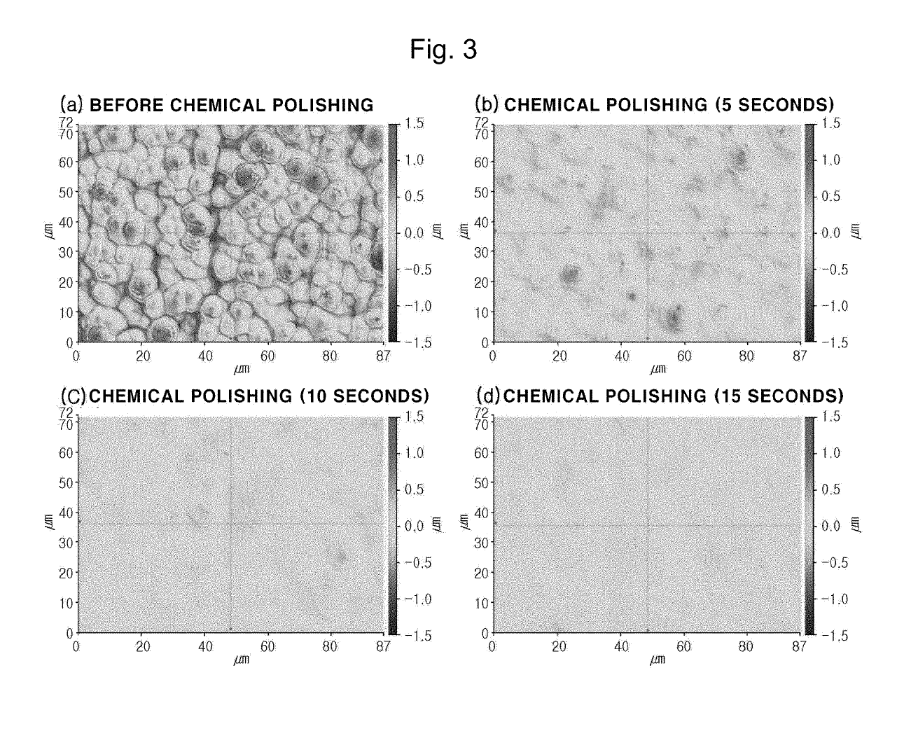

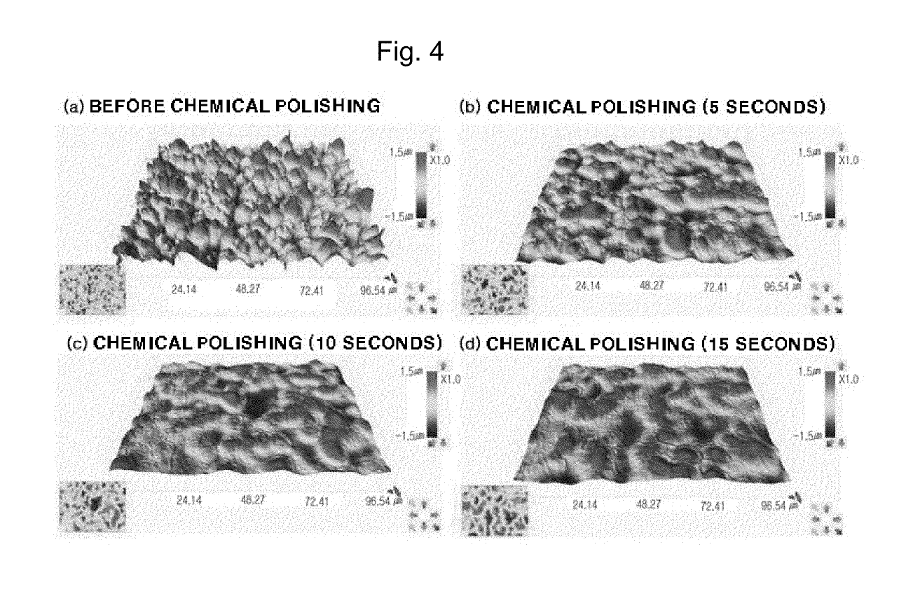

Also, 3D profiler images with respect to surface morphology of each metal foil obtained were presented in FIG. 3 and FIG. 4. FIG. 3 is 3D profiler plan view images of surfaces, and FIG. 4 is 3D profiler perspective view images of surfaces.

From FIG. 3 and FIG. 4, it could be known that the surface morphology becomes smooth in accordance with the polishing time.

Once a photoresist pattern is formed on the metal foils obtained in Comparative Example 1 and Inventive Example 3 through surface photolithography, etching was performed to form through-holes therein.

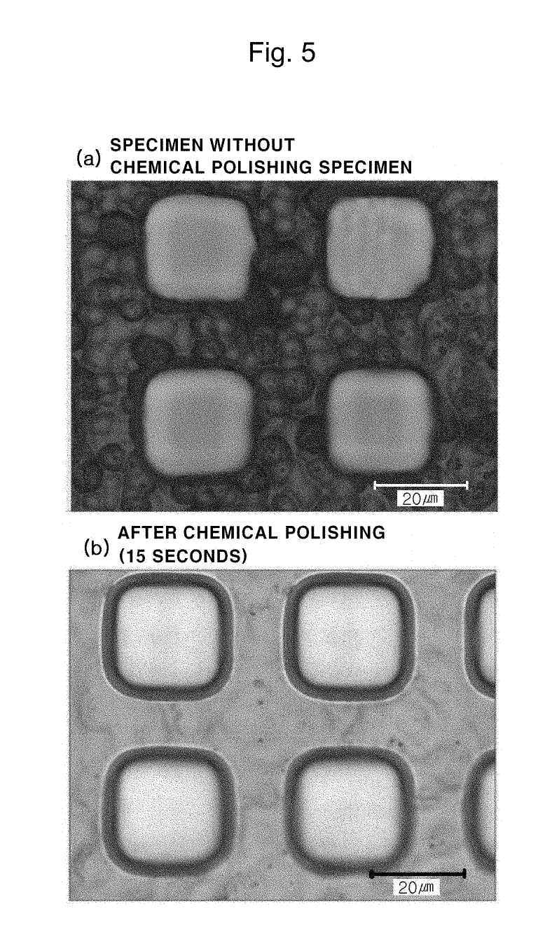

The through-holes thus obtained were photographed by an electron microscope, and the photographs were presented in FIG. 5.

As can be seen in FIG. 5, the through-holes formed on the chemically polished metal foil of Inventive Example 3 were formed with high uniformity without distortion. Also, the linearity of through-hole patterns thus formed was apparent.

Meanwhile, in the case of Comparative Example 1, boundaries between the through-holes were not clear, indicating a significantly reduced linearity of through-hole patterns. Also, distortions were observed in the formed through-holes due to surface roughness.

1. A Fe—Ni alloy metal foil for use as a deposition mask, comprising 34-46 wt % of nickel (Ni) and a balance of iron (Fe) and inevitable impurities,
wherein the metal foil includes, on at least one side thereof, a pattern formation area and an uncoated area, and
wherein the pattern formation area is thinner than the uncoated area and has a surface roughness value less than that of the uncoated area, and the uncoated area is positioned at an edge of the metal foil so as to surround the pattern formation area.

2. The Fe—Ni alloy metal foil for use as a deposition mask of claim 1, wherein the pattern formation area has a thickness that is 25-88% of a thickness of the uncoated area.

3. The Fe—Ni alloy metal foil for use as a deposition mask of claim 1, wherein the pattern formation area has a thickness in a range of 5-20 μm.

4. The Fe—Ni alloy metal foil for use as a deposition mask of claim 1, wherein the Fe—Ni alloy metal foil is produced by electroforming, and a surface roughness value of the pattern formation area is less than a surface roughness value of the uncoated area.

5. The Fe—Ni alloy metal foil for use as a deposition mask of claim 4, wherein the pattern formation area has a surface roughness value greater than or equal to 30% and less than or equal to 80% of a surface roughness value of the uncoated area.

6. A method of producing a Fe—Ni alloy metal foil for use as a deposition mask, the method comprising an operation of performing chemical polishing on a pattern formation area of one side of a Fe—Ni alloy metal foil, excluding an edge of the metal foil, to thin the pattern formation area, wherein the Fe—Ni alloy metal foil contains 34-46 wt % of nickel and a balance of iron and inevitable impurities.

7. The method of producing a Fe—Ni alloy metal foil for use as a deposition mask of claim 6, further comprising an operation of performing chemical polishing on an entire area of the other side of the metal foil to thin the metal foil.

8. A deposition mask formed by a Fe—Ni alloy metal foil having a predetermined pattern of through-holes formed therein,
wherein the metal foil contains 34-46 wt % of nickel (Ni) and a balance of iron (Fe) and inevitable impurities, and
wherein one side of the deposition mask is formed of a pattern formation area including the predetermined pattern of through-holes, and an uncoated area being thicker than the pattern formation area and not containing through-holes.

9. The deposition mask of claim 8, wherein the pattern formation area has a thickness that corresponds to 25-88% of a thickness of the uncoated area.

10. The deposition mask of claim 8, wherein the pattern formation area has a thickness in a range of 5-15 μm.

11. The deposition mask of claim 8, wherein inner wall surfaces of the through-holes are inclined such that gaps between the through-holes broaden from the one side including a pattern formation area and an uncoated area, towards the other side.

12. The deposition mask of claim 8, wherein the Fe—Ni alloy metal foil is produced by electroforming, and a surface roughness value of the pattern formation area is less than a surface roughness value of the uncoated area.

13. The deposition mask of claim 12, wherein the pattern formation area has a surface roughness value greater than or equal to 30% and less than or equal to 80% of a surface roughness value of the uncoated area.

14. The deposition mask of claim 12, wherein inner wall surfaces of the through holes include a plurality of stripe patterns in a direction parallel to a surface of the deposition mask.

15. The deposition mask of claim 12, wherein the other side of the deposition mask, disposed opposite to the one side including a pattern formation area and an uncoated area, has a surface roughness value lower than a surface roughness value of the uncoated area.

16.-18. (canceled)
